(19) United States
(12) Patent Application Publication
(10) Pub. No.: US 2014/0184348 A1
(43) Pub. Date: Jul. 3, 2014

(54) CIRCUIT FOR ADJUSTING FREQUENCY OF CRYSTAL OSCILLATOR

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: WU ZHOU, Shenzhen (CN); YANG GAO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/968,376

(22) Filed: Aug. 15, 2013

(30) Foreign Application Priority Data
Dec. 29, 2012 (CN) 2012105889395

(51) Int. Cl. H03L 7/00

(52) U.S. Cl. CPC H03L 7/00
USPC 331/36 C

(57) ABSTRACT

A circuit for adjusting frequency of a crystal oscillator includes a basic input output system (BIOS), a platform controller hub (PCH), a buffer, and a capacitor module with a number of capacitors. The crystal oscillator is connected to clock pins of the PCH. An input pin of the buffer is connected to the crystal oscillator. A first end of the each of the capacitors is connected to an output pin of the buffer. A second end of the each of the capacitors is grounded. The buffer includes two enable pins and a control unit controlled by the enable pins. The enable pins of the buffer receive a control signal from the PCH according to the BIOS, and control the control unit to appoint the corresponding capacitor of the capacitor module to be connected to the input pin of the buffer.

### BACKGROUND

1. Technical Field

The present disclosure relates to a circuit for adjusting frequency of a crystal oscillator.

2. Description of Related Art

Frequency of a crystal oscillator needs to be precisely tuned for electronic devices. The frequency of the crystal oscillator is usually tuned using two capacitors soldered to opposite ends of the crystal oscillator. If the frequency changes over time, the oscillator is retuned by replacing the capacitors. However, capacitance of the new capacitors may change as it can be affected by the soldering process.

Therefore, there is need for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a circuit diagram of an embodiment of a circuit for adjusting frequency of a crystal oscillator.

FIG. 2 is a circuit diagram of a buffer of the circuit of FIG. 1.

### DETAILED DESCRIPTION

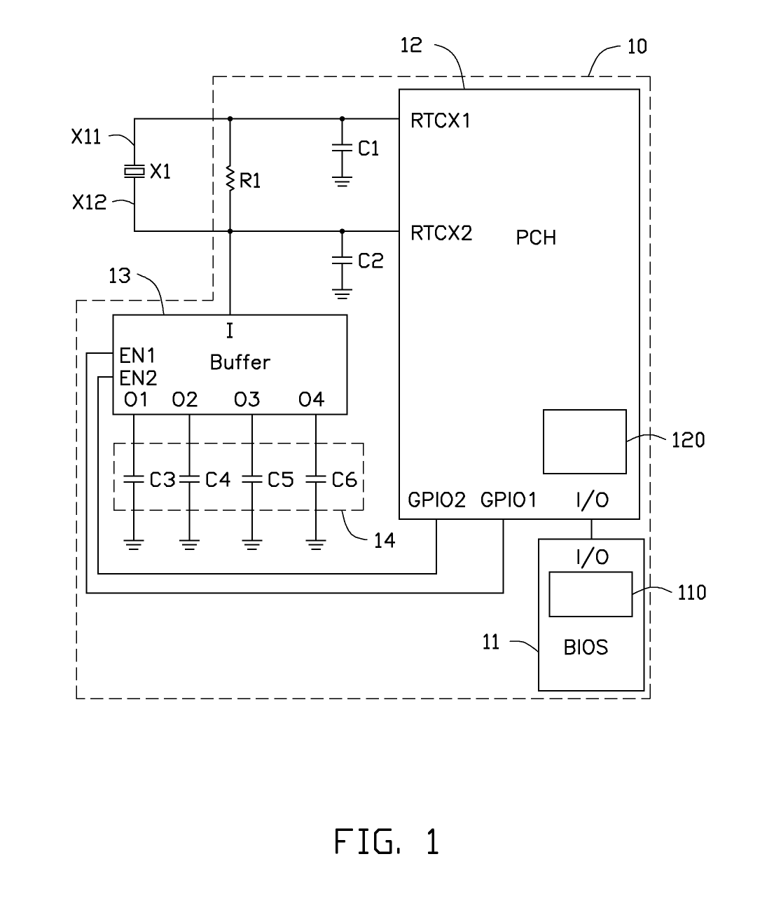

FIG. 1 is a circuit diagram of an embodiment of a circuit 10 for adjusting frequency of a crystal oscillator X1. The circuit 10 includes a basic input output system (BIOS) 11, a platform controller hub (PCH) 12, a buffer 13, and a capacitor module 14.

In the embodiment, the BIOS 11 is connected to the PCH 12 by serial peripheral interfaces (SPIs) through input output (I/O) pins of the BIOS 11 and the PCH 12, to make a first register 110 of the BIOS 11 transmit control signals to a second register 120 of the PCH 12. In the embodiment, the control signals output by the first register 110 of the BIOS 11 includes a first digital signal and a second digital signal. A first general purpose input output (GPIO) pin GPIO1 of the PCH 12 and a second GPIO pin GPIO2 of the PCH 12 receive the first digital signal and the second digital signal, respectively, from the second register 120 of the PCH 12, and output the first digital signal and the second digital signal to the buffer 13.

The crystal oscillator X1 includes a first end X11 and a second end X12. The first end X11 of the crystal oscillator X1 is connected to a first clock pin RTCX1 of the PCH 12, and is grounded through a capacitor C1. The second end X12 of the crystal oscillator X1 is connected to a second clock pin RTCX2 of the PCH 12, and is grounded through a capacitor C2. The first end X11 is connected to the second end X12 through a resistor R1. In the embodiment, capacitance of each of the first capacitor C1 and the second capacitor C2 is 18 picofarads (pF).

The buffer 13 includes a first enable pin EN1, a second enable pin EN2, an input pin I, and four output pins O1-O4. The input pin I is connected to the second end X12 of the crystal oscillator X1. The first enable pin EN1 is connected to, and receives the first digital signal from, the first GPIO pin GPIO1. The second enable pin EN2 is connected to, and receives the second digital signal from, the second GPIO pin GPIO2.

The capacitor module 14 includes four capacitors C3-C6. First ends of the capacitors C3-C6 are connected to the output pins O1-O4 of the buffer 13, respectively. Second ends of the capacitors C3-C6 are grounded. In the embodiment, capacitance of each of the capacitors C3-C6 is 1 pF.

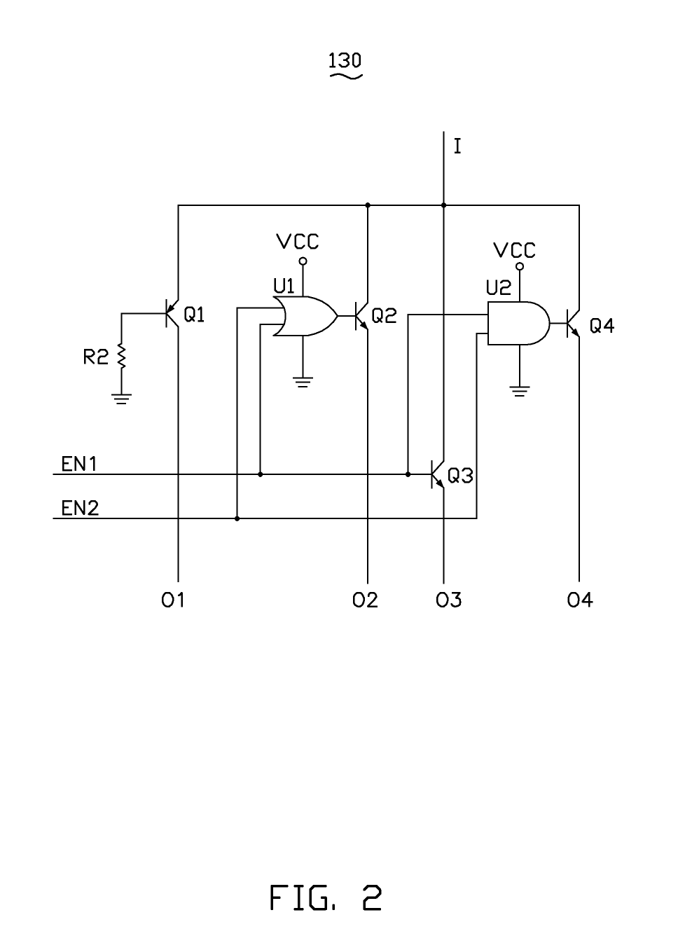

The buffer 13 further includes a control module 130. FIG. 2 shows a circuit diagram of the control module 130 of the buffer 13. The control module 130 includes first to fourth electronic switches Q1-Q4, an OR gate U1, and an AND gate U2. A first end of the first electronic switch Q1 is grounded through a resistor R2. A second end of the first electronic switch Q1 is connected to the input pin I of the buffer 13. A third end of the first electronic switch Q1 is connected to the output pin O1 of the buffer 13. A first input and a second input of the OR gate U1 are connected to the first enable pin EN1 and the second enable pin EN2 of the buffer 13, respectively. A first input and a second input of the AND gate U2 are connected to the first enable pin EN1 and the second enable pin EN2, respectively. A first end of the second electronic switch Q2 is connected to an output of the OR gate U1. A first end of the third electronic switch Q3 is connected to the first enable pin EN1 of the buffer 13. A first end of the fourth electronic switch Q4 is connected to an output of the AND gate U2. Second ends of the second to fourth electronic switches Q2-Q4 are connected to the second to fourth output pins O2-O4 of the buffer 13, respectively. Third ends of the second to fourth electronic switches Q2-Q4 are connected to the input pin I of the buffer 13.

In the embodiment, the first electronic switch Q1 is a pnp bipolar junction transistor. The second to fourth electronic switches Q2-Q4 are npn bipolar junction transistors. The first to third ends of the first to fourth electronic switches Q1-Q4 correspond to bases, emitters, and collectors of the bipolar junction transistors, respectively.

In use, when the first and second digital signals respectively received by the first and second enable pins EN1 and EN2 are low level signals, such as logic 0, the first electronic switch Q1 is turned on. The second to fourth electronic switches Q2-Q4 are turned off. Thereby, the capacitor C3 is connected to the input pin I through the first output pin O1 of the buffer 13, and is further connected to the crystal oscillator X1.

When the first digital signal received by the first enable pin EN1 is a low level signal, such as logic “0”, and the second digital signal received by the second enable pin EN2 is a high level signal, such as logic 1, the first and second electronic switches Q1 and Q2 are turned on. The third and fourth electronic switches Q3 and Q4 are turned off. Thereby, both of the capacitors C3 and C4 are connected to the input pin I of the buffer 13 through the first and second output pins O1 and O2, respectively, and are further connected to the crystal oscillator X1.

When the first digital signal received by the first enable pin EN1 is a high level signal, such as logic “1”, and the second digital signal received by the second enable pin EN2 is a low level signal, such as logic 0, the first to third electronic switches Q1-Q3 are turned on. The fourth electronic switch Q4 is turned off. Thereby, the capacitors C3-05 are connected to the input pin I of the buffer 13 through the first to third output pins O1-O3, respectively, and are further connected to the crystal oscillator X1.

When the first and second digital signals respectively received by the first and second enable pins EN1 and EN2 are high level signals with logic “1”, the first to fourth electronic switches Q1-Q4 are turned on. Thereby, the capacitors C3-C6 are connected to the input pin I of the buffer 13 through the first to fourth output pins O1-O4, respectively, and are further connected to the crystal oscillator X1.

Therefore, the frequency of the crystal oscillator X1 can be adjusted, according to the logic state of the first digital signal and the second digital signal received by the first enable pin EN1 and the second enable pin EN2, respectively, without the need to replace any capacitors.

In another embodiment, a number of the enable pins of the buffer 13 can be set according to a number of the capacitors connected to the buffer 13.

While the disclosure has been described by way of example and in terms of preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A circuit, comprising:
a basic input output system (BIOS) outputting a control signal;
a platform controller hub (PCH) receiving and outputting the control signal outputted from the BIOS, the PCH comprising a first clock pin connected to a first end of a crystal oscillator and a second clock pin connected to a second end of the crystal oscillator;
a buffer comprising an input pin, a plurality of output pins, a plurality of enable pins, and a control module, wherein the input pin is connected to the second end of the crystal oscillator, the plurality of enable pins receives the control signal from the PCH, to control the input pin to be connected to or disconnected from the corresponding output pins through the control module, according to a logic state of the control signal;
a capacitor module comprising a plurality of capacitors, wherein a first end of each capacitor is connected to a corresponding one of the plurality of output pins of the buffer; a second end of each capacitor is grounded; when the input pin of the buffer is controlled by the control module to be connected to one output pin of the buffer, the capacitor connected to the output pin is connected to the second end of the crystal oscillator.

2. The circuit of claim 1, wherein the BIOS comprises a first register, the PCH comprises a second register; the control signal comprises a first digital signal and a second digital signal; the first and second digital signals are outputted from the first register of the BIOS to the second register of the PCH, and transmitted to the buffer through a first general purpose input output (GPIO) pin and a second GPIO pin of the PCH, respectively.

3. The circuit of claim 2, wherein the plurality of enable pins of the buffer comprises a first enable pin and a second enable pin, the first and second enable pins are respectively connected to the first and second GPIO pins of the PCH, and receive the first and second digital signals, respectively; the first and second digital signals control the input pin to connect to or disconnect from the output pins of the buffer according to the logic state of the first and second digital signals.

4. The circuit of claim 3, wherein the plurality of output pins of the buffer comprises first to fourth output pins, the capacitor module comprises first to fourth capacitors, the control module comprises first to fourth electronic switches, an AND gate, and an OR gate; a first end of the first electronic switch is grounded through a first resistor, a second end of the first electronic switch is connected to the input pin of the buffer, a third end of the first electronic switch is connected to the first output pin of the buffer; a first input and a second input of the OR gate are connected to the first enable pin and the second enable pin, respectively; a first input and a second input of the AND gate are connected to the first enable pin and the second enable pin, respectively; a first end of the second electronic switch is connected to an output of the OR gate; a first end of the third electronic switch is connected to the first enable pin; a first end of the fourth electronic switch is connected to an output of the AND gate; second ends of the second to fourth electronic switches are connected to the second to fourth output pins of the buffer, respectively; third ends of the second to fourth electronic switches are connected to the input pin of the buffer.

5. The circuit of claim 4, wherein the first electronic switch is a pnp bipolar junction transistor, the second to fourth electronic switches are npn bipolar junction transistors, the first to third ends of the first to fourth electronic switches correspond to bases, emitters, and collectors of the bipolar junction transistors, respectively.

6. The circuit of claim 4, wherein capacitance of each of the first to fourth capacitors is 1 picofarad.

7. The circuit of claim 1, further comprising a resistor connected between the first end of the crystal oscillator and the second end of the crystal oscillator.

8. The circuit of claim 1, further comprising a first capacitor and a second capacitor, wherein first ends of the first and second capacitors are connected to the first end and second end of the crystal oscillator, respectively, second ends of the first and second capacitors are grounded.

9. The circuit of claim 8, wherein capacitance of each of the first and second capacitors is 18 picofarads.
